(19) United States
(12) Patent Application Publication
(10) Pub. No.: US 2014/0079087 A1
(43) Pub. Date: Mar. 20, 2014

(54) LIFT-OFF PROCESSING FOR FORMATION OF ISOLATION REGIONS IN LASER DIODE STRUCTURES

(71) Applicant: CORNING INCORPORATION, Corning, NY (US)

(72) Inventors: Shiwen Liu, Painted Post, NY (US); Barry J. Paddock, Horseheads, NY (US); Chung-En Zah, Holmdel, NJ (US)

(73) Assignee: CORNING INCORPORATED a New York corporation

(21) Appl. No.: 14/119,607

(22) PCT Filed: May 22, 2012
(86) PCT No.: PCT/US2012/038928

§ 371 Date: Nov. 22, 2013

Related U.S. Application Data
(60) Provisional application No. 61/490,753, filed on May 27, 2011.

(51) Int. Cl. H01S 5/026

(52) U.S. Cl. CPC H01S 5/026
USPC 372/50.1; 438/31

(57) ABSTRACT

A method of fabricating a laser diode structure is provided where a photolithographic process is utilized to form at least a portion of an axially extending waveguide structure such that a patterned photoresist remnant resides over the axially extending waveguide structure following the photolithographic process. A patterned isolated opening and a lift-off photoresist portion are formed in the patterned photoresist remnant by subjecting the patterned photoresist remnant to an additional photolithographic process such that the lift-off photoresist portion remains in residence over the axially extending waveguide structure following the additional photolithographic process. An insulating layer is formed over the patterned isolated opening and the lift-off photoresist portion.

### CROSS-REFERENCE To RELATED APPLICATIONS

This application claims the benefit of priority under 35 U.S.C. §119 of U.S. Provisional Application Ser. No. 61/490,753, filed on May 27, 2011, the content of which is relied upon and incorporated herein by reference in its entirety.

### BACKGROUND

1. Field

The present disclosure relates to laser diode fabrication and, more generally, to photolithographic techniques in semiconductor processing.

2. Technical Background

Fabrication processes for laser diodes and other semiconductor devices commonly employ photolithographic techniques and related processing steps. These photolithographic techniques can be relatively complex.

### BRIEF SUMMARY

Methods of fabricating laser diodes and other semiconductor structures are provided where lift-off processing is utilized to leave a patterned isolation region of an insulating layer in residence over the axially extending waveguide structure of the laser diode. Resulting semiconductor structures of novel configuration are also contemplated.

In accordance with one embodiment of the present disclosure, a method of fabricating a laser diode structure is provided where a photolithographic process is utilized to form at least a portion of an axially extending waveguide structure such that a patterned photoresist remnant resides over the axially extending waveguide structure following the photolithographic process. A patterned isolated opening and a lift-off photoresist portion are formed in the patterned photoresist remnant by subjecting the patterned photoresist remnant to an additional photolithographic process such that the lift-off photoresist portion remains in residence over the axially extending waveguide structure following the additional photolithographic process. An insulating layer is formed over the patterned isolated opening and the lift-off photoresist portion. The insulating layer and the underlying lift-off photoresist portion are subject to a lift-off process to leave a patterned isolation region of the insulating layer in residence over the axially extending waveguide structure. Additional embodiments are contemplated where the concepts of the present disclosure are applied more generally to laser diode structures and photolithographic techniques in semiconductor processing.

### BRIEF DESCRIPTION OF THE DRAWINGS

The following detailed description of specific embodiments of the present disclosure can be best understood when read in conjunction with the following drawings, where like structure is indicated with like reference numerals and in which:

FIG. 1 is a schematic illustration of a wavelength selective portion of a ridge waveguide laser diode structure including a patterned isolation region fabricated according to the photolithographic methodology of the present disclosure;

FIGS. 2A and 2B illustrate initial photolithographic patterning steps of the present disclosure in the context of a ridge waveguide laser diode structure;

FIGS. 3A and 3B illustrate ridge formation following the initial photolithographic patterning steps illustrated in FIGS. 2A and 2B;

FIGS. 4A and 4B illustrate formation of a patterned isolated opening and a lift-off photoresist portion following the ridge formation illustrated in FIGS. 3A and 3B;

FIGS. 5A and 5B illustrate insulating layer deposition following formation of the patterned isolated opening illustrated in FIGS. 4A and 4B;

FIG. 6 illustrates patterned lift off processing following the insulating layer deposition illustrated in FIGS. 5A and 5B; and

FIGS. 7A-7C illustrate formation of a control element over the patterned isolation region of FIG. 6.

### DETAILED DESCRIPTION

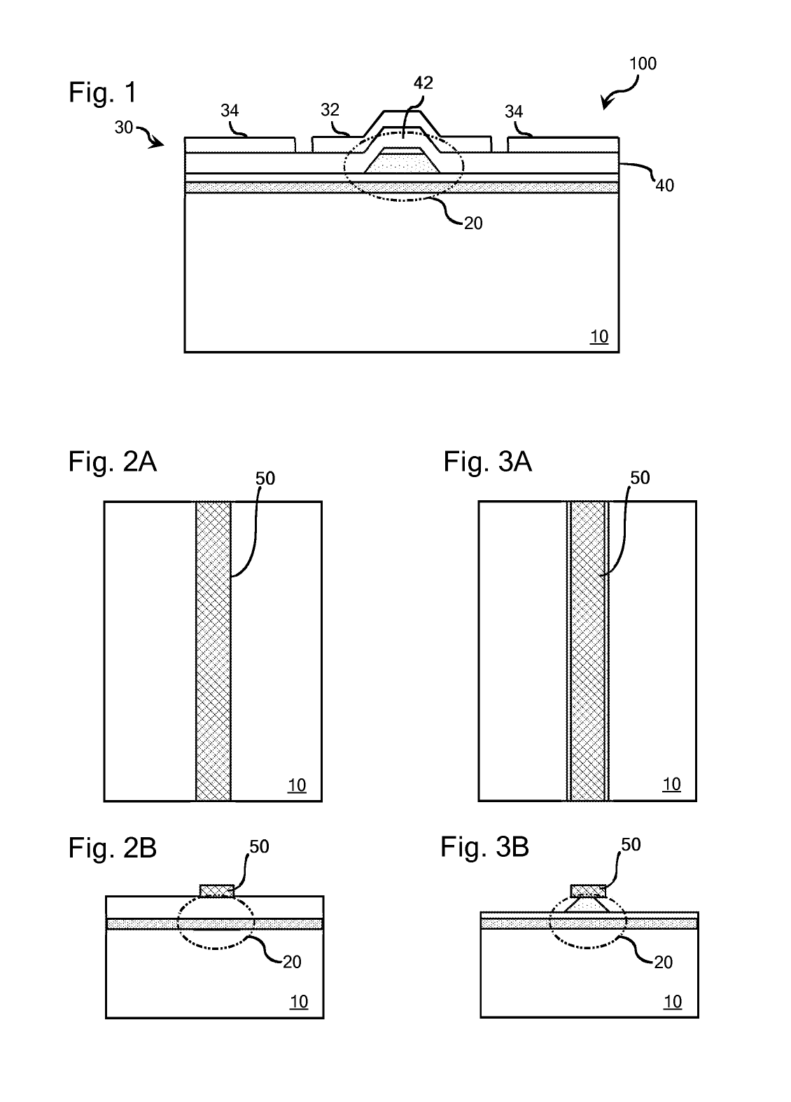

Methods of fabricating laser diode and other semiconductor structures in accordance with the teachings of the present disclosure can be conveniently illustrated with reference to the laser diode structure 100 of FIG. 1, where the laser diode structure 100 comprises a semiconductor substrate 10, an axially extending waveguide structure 20, a control element 30 in the form of, for example, a heating structure comprising a heating element 32 extending over the limited axial portion of the waveguide structure 20 and heater pads 34 for wire bonding. An insulating layer 40 is positioned over the semiconductor substrate 10 and between the control element 30 and the waveguide structure 20. For the purposes of defining and describing the present invention, it is noted that reference herein to an “axial” portion of the waveguide structure 20 or laser diode structure 100 is intended to refer to the longitudinal direction in which light propagates in the structure, which direction extends perpendicular to the illustration plane of FIG. 1.

The initial steps of a photolithographic process according to the present disclosure can be illustrated with reference to FIGS. 2A and 2B, where a photolithographic process is utilized to form at least a portion of the axially extending waveguide structure 20 such that a patterned photoresist remnant 50 resides over the axially extending waveguide structure 20 following the photolithographic process. Beyond that which is disclosed herein, the particulars of photolithographic processing, and the materials utilized therein, can be readily gleaned from conventional or yet to be developed teachings on the subject and do not form an essential part of the present disclosure.

Similarly, it is noted that the laser diode structure 100 in general and the waveguide structure 20 in particular are not described or illustrated in detail herein because these structures can take a variety of conventional and yet to be developed forms, only one of which is illustrated schematically in FIG. 1, and all of which can be gleaned from suitable teachings in the art. For example, it is contemplated that the laser diode structure 100 may comprise a ridge waveguide. Referring to FIGS. 3A and 3B, for example, it is contemplated that the methodology of the present disclosure may comprise an etching step where a waveguide ridge including the patterned photoresist remnant 50 and a least a portion of the axially extending waveguide structure 20 is formed in the semiconductor substrate 10. In the illustrated embodiment, the patterned photoresist remnant 50 resides over an entirety of the axially extending waveguide structure 20.

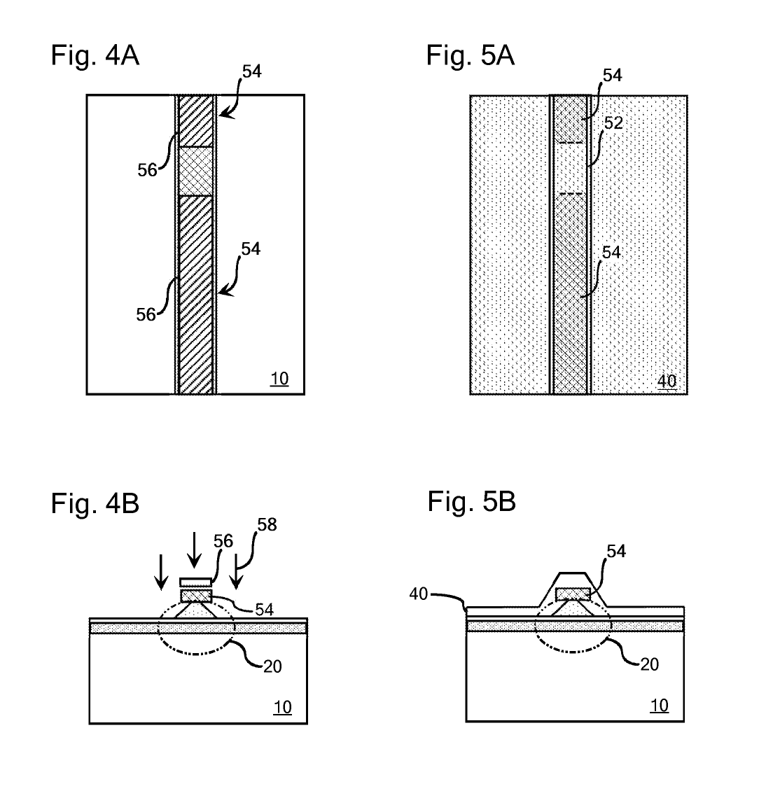

Referring collectively to FIGS. 4 and 5, a patterned isolated opening 52 and a lift-off photoresist portion 54 (see FIGS. 5A and 5B) are formed in the patterned photoresist remnant 50 by subjecting the patterned photoresist remnant 50 to an additional photolithographic process (see FIGS. 4A and 4B) utilizing a photolithographic mask 56 and corresponding exposure 58 to define the bounds of the patterned isolated opening 52 and the lift-off photoresist portion 54. As is illustrated in FIGS. 5A and 5B, the lift-off photoresist portion 54 remains in residence over the axially extending waveguide structure 20 following the additional photolithographic process of FIGS. 4A and 4B. The insulating layer 40 is formed over the patterned isolated opening 52 and the lift-off photoresist portion 54.

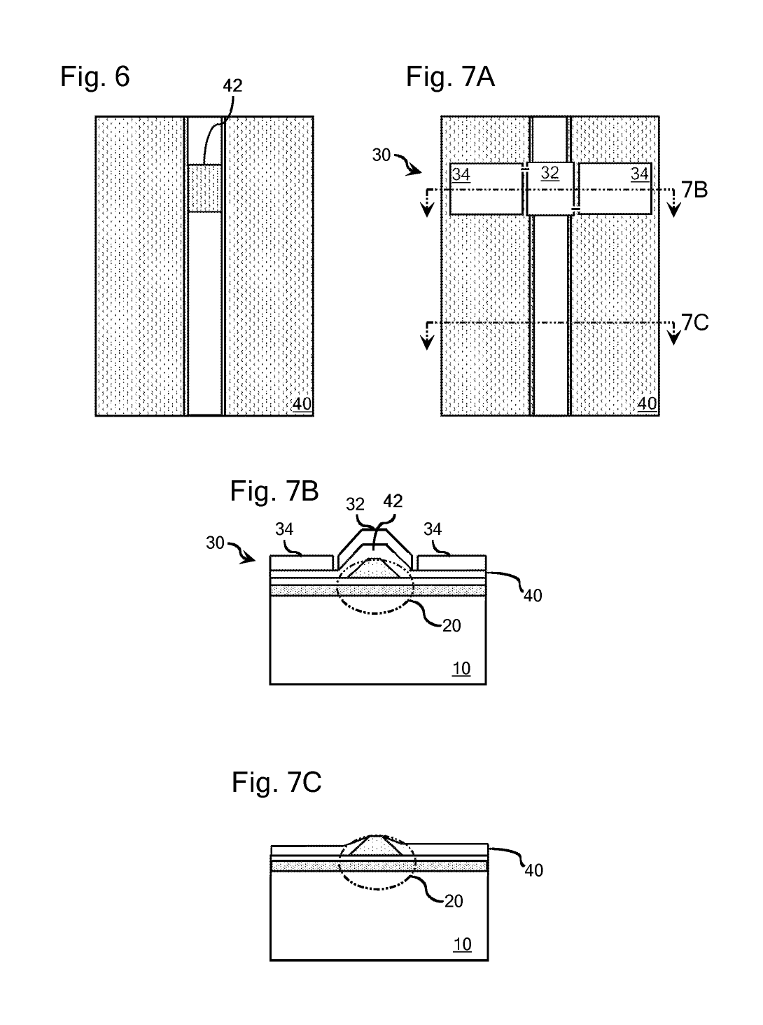

Referring to FIG. 6, the insulating layer 40 and the underlying lift-off photoresist portion 54 are subsequently subject to a lift-off process to leave a patterned isolation region 42 of the insulating layer 40 in residence over the axially extending waveguide structure 20. According to one embodiment of the present disclosure, the insulating layer 40 comprises silicon nitride, more particularly Si₃N₄, and is formed over the patterned isolated opening 52 and the lift-off photoresist portion 54 at a temperature that does not exceed the hard bake temperature of the lift-off photoresist portion 54, e.g., at a temperature that does not exceed 200° C. This low temperature formation of the insulating layer 40 helps to ensure the integrity of the lift-off process described herein and permits device fabrication using the same photoresist coating in multiple masking steps. More specifically, the semiconductor wafer to be processed is initially masked and exposed to form a portion of the axially extending waveguide of FIG. 2. The patterned photoresist remnant is subsequently masked and exposed again in the additional photolithographic process of FIG. 4 before putting on the low temperature insulating layer and without applying fresh photoresist. Thus, multiple insulating layer deposition steps or surface damaging etching steps are not required.

Additional insulating layer compositions are contemplated including, for example, silicon oxide, e.g., SiO₂, TiO₂ and ZrO₂. Beyond this, it is noted that the particulars of conventional and yet-to-be developed semiconductor lift-off processing are beyond the scope of the present disclosure and can be gleaned from suitable teachings in the art.

FIGS. 7A-7C illustrate the manner in which a portion of the control element 30 can be formed over the patterned isolation region 42 of the insulating layer 40, which region 42 lies in residence over the axially extending waveguide structure 20. It is contemplated that, in addition to the heating element 32 and heater pads 34 illustrated in FIGS. 7A and 7B, the control element 30 may alternatively comprise control electrodes or other conventional or yet to be developed elements for controlling a section of the laser diode structure 100. The laser diode structure itself may be configured in a variety of ways including, for example, as a double heterostructure laser, a quantum well laser, a quantum cascade laser, a DBR semiconductor laser, a DFB semiconductor laser, or an external cavity laser.

Accordingly, referring collectively to FIGS. 7A-7C, laser diode structures are contemplated where the structure comprises a semiconductor substrate 10, an axially extending waveguide structure 20, a control element 30 extending over a limited axial portion of the waveguide structure 20, and a patterned isolation region 42 of an insulating layer 40, which region 42 lies in residence over the axially extending waveguide structure 20. At least a portion of the control element 30 is formed over the insulating layer 40 and the patterned isolation region 42 in residence over the axially extending waveguide structure 20. The patterned isolation region 42 of the insulating layer 40 and the control element 30 reside substantially contiguously over the waveguide structure 20 along a limited axial dimension of the waveguide structure 20.

For example, and not by way of limitation, where the laser diode structure 100 comprises a DBR semiconductor laser, the patterned isolation region 42 can be tailored to reside over a wavelength selective DBR portion of the laser. More generally, the limited axial dimension of the waveguide structure 20 may correspond to a wavelength selective portion of the laser diode structure and the control element may be configured to control a wavelength selective characteristic of the wavelength selective portion of the laser diode structure. More generally still, the laser diode structure may comprise a plurality of functional regions and the patterned isolation region may be formed over one of the functional regions of the laser diode structure to isolate electrically the gain section of the laser diode from the control element. Alternatively, the isolation region may be formed near the laser facet as an unpumped window section of the laser diode.

For the purposes of describing and defining the present invention, it is noted that a “semiconductor substrate” denotes any construction comprising a semiconductor material. Examples of semiconductor substrates include semiconductor wafers or other bulk semiconductor materials (either alone or in assemblies comprising other materials), and semiconductor material layers (either alone or in assemblies comprising other materials). It should be further noted that, for the purposes of defining and describing the present invention, reference herein to a layer or material being formed “over” a substrate or another layer or material denotes formation above or in contact with the surface of the underlying substrate or layer and does not preclude the presence of intervening layers.

It is noted that recitations herein of a component of the present disclosure being “configured” in a particular way, to embody a particular property, or function in a particular manner, are structural recitations, as opposed to recitations of intended use. More specifically, the references herein to the manner in which a component is “configured” denotes an existing physical condition of the component and, as such, is to be taken as a definite recitation of the structural characteristics of the component.

It is noted that terms like “preferably,” “commonly,” and “typically,” when utilized herein, are not utilized to limit the scope of the claimed invention or to imply that certain features are critical, essential, or even important to the structure or function of the claimed invention. Rather, these terms are merely intended to identify particular aspects of an embodiment of the present disclosure or to emphasize alternative or additional features that may or may not be utilized in a particular embodiment of the present disclosure.

For the purposes of describing and defining the present invention it is noted that the term “substantially” is utilized herein to represent the inherent degree of uncertainty that may be attributed to any quantitative comparison, value, measurement, or other representation. The term “substantially” is also utilized herein to represent the degree by which a quantitative representation may vary from a stated reference without resulting in a change in the basic function of the subject matter at issue.

Having described the subject matter of the present disclosure in detail and by reference to specific embodiments thereof, it is noted that the various details disclosed herein should not be taken to imply that these details relate to elements that are essential components of the various embodiments described herein, even in cases where a particular element is illustrated in each of the drawings that accompany the present description. Rather, the claims appended hereto should be taken as the sole representation of the breadth of the present disclosure and the corresponding scope of the various inventions described herein. Further, it will be apparent that modifications and variations are possible without departing from the scope of the invention defined in the appended claims. More specifically, although some aspects of the present disclosure are identified herein as preferred or particularly advantageous, it is contemplated that the present disclosure is not necessarily limited to these aspects.

It is noted that one or more of the following claims utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising.”

1. A method of fabricating a laser diode structure comprising a semiconductor substrate, an axially extending waveguide structure, and an insulating layer positioned over the semiconductor substrate, wherein the method comprises:
utilizing a photolithographic process to form at least a portion of the axially extending waveguide structure such that a patterned photoresist remnant resides over the axially extending waveguide structure following the photolithographic process;
forming a patterned isolated opening and a lift-off photoresist portion in the patterned photoresist remnant by subjecting the patterned photoresist remnant to an additional photolithographic process such that the lift-off photoresist portion remains in residence over the axially extending waveguide structure following the additional photolithographic process;
forming the insulating layer over the patterned isolated opening and the lift-off photoresist portion; and
subjecting the insulating layer and underlying lift-off photoresist portion to a lift-off process to leave a patterned isolation region of the insulating layer in residence over the axially extending waveguide structure.

2. A method as claimed in claim 1 wherein the insulating layer comprises silicon nitride and is formed over the patterned isolated opening and the lift-off photoresist portion at a temperature that does not exceed a hard bake temperature of the lift-off photoresist portion.

3. A method as claimed in claim 1 wherein the insulating layer comprises silicon nitride and is formed over the patterned isolated opening and the lift-off photoresist portion at a temperature that does not exceed 200° C.

4. A method as claimed in claim 1 wherein the insulating layer comprises silicon nitride presented in the form of Si₃N₄.

5. A method as claimed in claim 1 wherein the insulating layer comprises silicon oxide and is formed over the patterned isolated opening and the lift-off photoresist portion at a temperature that does not exceed a hard bake temperature of the lift-off photoresist portion.

6. A method as claimed in claim 1 wherein the insulating layer comprises silicon oxide and is formed over the patterned isolated opening and the lift-off photoresist portion at a temperature that does not exceed 200° C.

7. A method as claimed in claim 1 wherein the insulating layer comprises silicon oxide presented in the form of SiO₂.

8. A method as claimed in claim 1 wherein a waveguide ridge including the patterned photoresist remnant and a least a portion of the axially extending waveguide structure is formed in the semiconductor substrate.

9. A method as claimed in claim 8 wherein the waveguide ridge is formed by etching the semiconductor substrate.

10. A method as claimed in claim 1 wherein:
the laser diode structure further comprises a control element extending over a limited axial portion of the waveguide structure; and
at least a portion of the control element is formed over the patterned isolation region in residence over the axially extending waveguide structure.

11. A method as claimed in claim 10 wherein the control element comprises a heating element extending over the limited axial portion of the waveguide structure and heater pads conductively coupled to the heating element.

12. A method as claimed in claim 1 wherein the laser diode structure comprises a plurality of functional regions and the patterned isolation region is formed over one of the functional regions of the laser diode structure to isolate electrically a gain section of the laser diode structure.

13. A method as claimed in claim 1 wherein the laser diode structure comprises a laser facet and the isolation region is formed near the laser facet as an unpumped window section of the laser diode.

14. A method as claimed in claim 1 wherein the laser diode structure comprises a ridge waveguide.

15. A method as claimed in claim 1 wherein the laser diode structure comprises a double heterostructure laser, a quantum well laser, a quantum cascade laser, a DBR semiconductor laser, a DFB semiconductor laser, or an external cavity laser.

16. A method as claimed in claim 1 wherein the laser diode structure comprises a DBR semiconductor laser and the patterned isolation region is formed over a wavelength selective DBR portion of the laser.

17. A laser diode structure comprising a semiconductor substrate, an axially extending waveguide structure, a control element extending over a limited axial portion of the waveguide structure; and a patterned isolation region of an insulating layer, which region lies in residence over the axially extending waveguide structure, wherein:
at least a portion of the control element is formed over the patterned isolation region in residence over the axially extending waveguide structure;
the patterned isolation region, the control element, and a waveguide portion of the insulating layer reside substantially contiguously over the waveguide structure along a limited axial dimension of the waveguide structure.

18. A laser diode structure as claimed in claim 17 wherein:
the limited axial dimension of the waveguide structure corresponds to a wavelength selective portion of the laser diode structure; and
the control element is configured to control a wavelength selective characteristic of the wavelength selective portion of the laser diode structure.

19. A laser diode structure as claimed in claim 18 wherein the control element comprises a heating element extending over the limited axial portion of the waveguide structure.

20. A laser diode structure as claimed in claim 17 wherein:
the limited axial dimension of the waveguide structure corresponds to a wavelength selective portion of the laser diode structure; and
the laser diode structure further comprises one or more unpumped window sections that are isolated electrically from the control element by the patterned isolation region.
